(19) United States
(12) Patent Application Publication
(10) Pub. No.: US 2026/0305012 A1
(43) Pub. Date: Oct. 1, 2026

(54) Three-dimensional photovoltaic module

(71) Applicant: Sylvain GAUTHIER, ÉZE (FR)

(72) Inventor: Sylvain GAUTHIER, ÉZE (FR)

(21) Appl. No.: 19/479,117

(22) PCT Filed: Sep. 4, 2023
(86) PCT No.: PCT/FR2023/051330

§ 371 Date: Oct. 27, 2025

(30) Foreign Application Priority Data
Apr. 27, 2023 (FR) FR23/04293

(51) Int. Cl. H10F 77/30; H10F 19/50; H10F 19/85

(52) U.S. Cl. CPC H10F 77/315; H10F 19/50; H10F 19/85

(57) ABSTRACT

The three-dimensional photovoltaic module provided with a central axis and includes a three-dimensional support structure including support faces distributed about the central axis; and photovoltaic coatings fastened to the three-dimensional support structure, each photovoltaic coating being disposed on a respective support face and at least in part covering the respective support face, each photovoltaic coating extending substantially along a respective plane of extension. The photovoltaic coatings including sub-assemblies of photovoltaic coatings which are distributed about the central axis and which each include two adjacent photovoltaic coatings the planes of extension of the two photovoltaic coatings belonging to the same sub-assembly intersecting along a respective line of intersection which is inclined relative to the central axis and which extends upwards and away from the central axis.

### CROSS-REFERENCE TO RELATED APPLICATIONS

This application is a 35 U.S.C. § 371 National Stage patent application of no. PCT/FR2023/051330, filed on 4 Sep. 2023, which claims the benefit of French patent application no. 23/04293, filed on 27 Apr. 2023, the disclosures of which are incorporated herein by reference in their entirety.

### TECHNICAL FIELD

The present disclosure relates generally to the field of photovoltaic solar energy. It more specifically relates to a three-dimensional photovoltaic module.

### BACKGROUND

In the field of photovoltaic solar energy, it is known to use, in general, two-dimensional photovoltaic panels formed by the superposition of several layers generally consisting from top to bottom of:
an anti-reflective coating to limit the reflection of solar rays on the underlying semiconductor layers;
a protective glass layer to protect the underlying semiconductor layers;
a conductive grid;
a N- or P-doped semiconductor layer;
a P- or N-doped semiconductor layer; and
a base layer.

The major drawback of this type of photovoltaic panel lies in the low amount of energy produced per m². Indeed, with a two-dimensional photovoltaic panel, the amount of energy produced per m² is not optimized.

Furthermore, this type of photovoltaic panel does not have a uniform energy production throughout the day. Indeed, this production follows a Gaussian law, maximum when the Sun is at its culmination point, and lower the rest of the day and in particular at the beginning and end of the day.

Furthermore, the conventional solution requires orienting the photovoltaic panel optimally in relation to solar radiation, which is not always easy depending on the configuration of the building receiving such a photovoltaic panel.

To overcome such drawbacks, it is known to produce a three-dimensional photovoltaic module including:
a three-dimensional support structure having a pyramidal shape with a square base, and comprising four support faces each having a triangular shape; and
a plurality of photovoltaic coatings fastened to the three-dimensional support structure, each photovoltaic coating being disposed on a respective support face and extending substantially parallel to the respective support face, each photovoltaic coating comprising at least one photovoltaic cell and at least in part covering the respective support face.

Such a configuration of the three-dimensional photovoltaic module makes it possible to increase the developed surface covered with active photovoltaic material, and therefore to produce, when the Sun is at its culmination point and the three-dimensional photovoltaic module is disposed on a horizontal surface, more energy per unit area than a conventional photovoltaic panel.

However, due to the shadows cast by the three-dimensional support structure during the Sun's path during a day, the amount of energy produced annually by such a three-dimensional photovoltaic module is not optimal. In addition, at certain times during the Sun's path, some of the photovoltaic coatings are not insolated and generate resistive loads that oppose the energy provided by the insolated photovoltaic coatings, which further limits the amount of energy produced annually by such a three-dimensional photovoltaic module.

Furthermore, when a plurality of three-dimensional photovoltaic modules of the aforementioned type are assembled together to form a photovoltaic device, each three-dimensional support structure generates, during the Sun's path, shadows, or even darkness, on the photovoltaic coatings of the adjacent three-dimensional photovoltaic modules, which therefore considerably limits the quantity of energy produced annually by such a photovoltaic device.

### SUMMARY

The present disclosure aims to remedy the drawbacks mentioned above.

The technical problem underlying the disclosure therefore consists in providing a three-dimensional photovoltaic module capable of producing more energy annually per unit area than a conventional three-dimensional photovoltaic module.

To this end, the present disclosure relates to a three-dimensional photovoltaic module having a central axis and including:
a three-dimensional support structure comprising a plurality of support faces distributed about the central axis,
photovoltaic coatings fastened to the three-dimensional support structure, each photovoltaic coating being disposed on a respective support face and at least in part covering the respective support face, each photovoltaic coating extending substantially along a respective plane of extension and comprising at least one photovoltaic cell,
the photovoltaic coatings comprising a plurality of sub-assemblies of photovoltaic coatings which are distributed about the central axis and which each include two adjacent photovoltaic coatings, the planes of extension of the two photovoltaic coatings belonging to the same sub-assembly converging upwards and intersecting along a respective line of intersection which is inclined relative to the central axis and which extends upwards while getting away from the central axis.

Such an orientation of the different photovoltaic coatings makes it possible to maximize the insolated surface of the three-dimensional photovoltaic module at each instant of the Sun's path, and therefore to capture a significant quantity of energy coming from the Sun, without requiring any movement mechanism configured to modify the orientation of the three-dimensional photovoltaic module depending on the position of the Sun.

In particular, the arrangement of the different photovoltaic coatings limits the phenomenon of shadows cast by each photovoltaic coating on the other photovoltaic coatings, while allowing good light penetration within the three-dimensional photovoltaic module.

Furthermore, given the arrangement of the photovoltaic coatings, all the photovoltaic coatings are at least partly simultaneously insolated during a significant part of the Sun's path, which ensures better regularity of energy production during the course of a day (and in particular during the ascending and descending phases of the Sun) and therefore also during the year. The arrangement of the photovoltaic coatings also makes it possible to produce electricity earlier in the day and until later in the day compared to the three-dimensional photovoltaic modules of the prior art.

Furthermore, when a photovoltaic coating is not directly insolated, it is nevertheless capable of capturing at least part of the light reflected by other photovoltaic coatings of the three-dimensional photovoltaic module. Finally, even when a photovoltaic coating is neither directly nor indirectly insolated, this represents only a minimal part of the photovoltaic coatings belonging to the three-dimensional photovoltaic module which is not insolated.

Therefore, the three-dimensional photovoltaic module makes it possible to produce, not only instantly, but especially annually, more energy per unit area than a conventional photovoltaic panel and also than a conventional three-dimensional photovoltaic module.

The three-dimensional photovoltaic module may further have one or several of the following features, taken alone or in combination.

According to one embodiment of the disclosure, the ratio of the developed surface of the photovoltaic coatings to the ground surface occupied by the three-dimensional photovoltaic module is greater than 3, and for example comprised between 4 and 6, and advantageously between 4.5 and 5.5. These arrangements ensure relatively high energy production, per unit area, compared to the energy produced, per unit area, by a three-dimensional photovoltaic module of the prior art.

According to one embodiment of the disclosure, the lines of intersection are regularly distributed about the central axis of the three-dimensional photovoltaic module.

According to one embodiment of the disclosure, each photovoltaic coating includes an active face configured to capture photons of incident light rays, and a passive face configured to be oriented towards the respective support face and provided with a negative terminal and a positive terminal.

According to one embodiment of the disclosure, the three-dimensional photovoltaic module includes electrical connection devices each configured to be electrically connected to the negative and positive terminals of a respective photovoltaic coating, each support face being perforated and including at least one through opening configured to allow an electrical connection between the negative and positive terminals of the respective photovoltaic coating and the respective electrical connection device.

According to one embodiment of the disclosure, each electrical connection device includes two electrical connection wires which extend through the respective through opening and which are connected respectively to the negative and positive terminals of the respective photovoltaic coating.

According to one embodiment of the disclosure, each photovoltaic coating extends substantially parallel to the respective support face.

According to one embodiment of the disclosure, each line of intersection intersects the central axis of the three-dimensional photovoltaic module.

According to one embodiment of the disclosure, the lines of intersection intersect at a point of intersection located substantially on the central axis of the three-dimensional photovoltaic module.

According to one embodiment of the disclosure, all the planes of extension of the photovoltaic coatings have different orientations.

According to one embodiment of the disclosure, the two photovoltaic coatings of each sub-assembly define an apex area, said apex areas being distributed, and for example regularly distributed, about the central axis.

According to one embodiment of the disclosure, the apex areas defined by the photovoltaic coatings are equidistant from the central axis.

According to one embodiment of the disclosure, the central axis of the three-dimensional photovoltaic module is configured to extend substantially vertically when the three-dimensional photovoltaic module is disposed on a horizontal surface.

According to one embodiment of the disclosure, the photovoltaic coatings of said plurality of photovoltaic coatings are distinct from one another and are connected in series and/or in parallel.

According to one embodiment of the disclosure, at least one photovoltaic coating, and for example each of the photovoltaic coatings, is flexible.

According to another embodiment of the disclosure, at least one photovoltaic coating, and for example each of the photovoltaic coatings, is rigid.

According to one embodiment of the disclosure, each photovoltaic coating comprises a plurality of photovoltaic cells connected in parallel and/or in series.

According to one embodiment of the disclosure, each of the photovoltaic coatings has a generally triangular shape.

According to one embodiment of the disclosure, each photovoltaic coating includes a first edge extending along and close to the respective line of intersection, a second edge located opposite the central axis and a third edge connecting the respective first and second edges.

According to one embodiment of the disclosure, the first edges of two photovoltaic coatings belonging to the same sub-assembly extend along and close to each other.

According to one embodiment of the disclosure, the second edge of each photovoltaic coating is inclined relative to the central axis, such that the lower end of said second edge is closer to the central axis than the upper end of said second edge.

According to one embodiment of the disclosure, each photovoltaic coating is inclined, relative to a respective reference plane which is parallel to the central axis and which passes through the third edge of said photovoltaic coating, by an angle of inclination comprised between 5 and 10°, and for example approximately 7°.

According to one embodiment of the disclosure, the first edge of each photovoltaic coating has a length comprised between 35 and 55 mm, and advantageously between 40 and 50 mm, and for example approximately 44 mm.

According to one embodiment of the disclosure, the second edge of each photovoltaic coating has a length comprised between 55 and 75 mm, and advantageously between 60 and 70 mm, and for example approximately 65 mm.

According to one embodiment of the disclosure, the third edge of each photovoltaic coating has a length comprised between 25 and 45 mm, and advantageously between 30 and 40 mm, and for example approximately 34 mm.

According to one embodiment of the disclosure, each of the lines of intersection is inclined relative to the central axis by an angle of inclination comprised between 10 and 40°, advantageously between 20 and 30°, and for example approximately 26°.

According to one embodiment of the disclosure, the number of support faces, and therefore of photovoltaic coatings, is comprised between 6 and 12.

According to one embodiment of the disclosure, the two photovoltaic coatings of each sub-assembly are substantially symmetrical with respect to a respective plane of symmetry passing through the respective line of intersection.

According to one embodiment of the disclosure, the planes of symmetry of the different sub-assemblies intersect along a line of intersection which is substantially coincident with the central axis.

According to one embodiment of the disclosure, the adjacent photovoltaic coatings belonging to two adjacent sub-assemblies are located opposite each other.

According to one embodiment of the disclosure, the two photovoltaic coatings of each sub-assembly define, in top view, a triangular shape, and for example an equilateral triangular shape. In other words, an orthogonal projection of all the points of the two photovoltaic coatings belonging to the same sub-assembly onto a reference plane perpendicular to the central axis defines a surface of triangular shape, and preferably of equilateral triangular shape.

According to one embodiment of the disclosure, a ratio of the first edge of each photovoltaic coating to a side of the equilateral triangular shape is comprised between 1.7 and 2.2, advantageously between 1.8 and 2, and for example between 1.90 and 1.95.

According to one embodiment of the disclosure, a ratio of the second edge of each photovoltaic coating to a side of the equilateral triangular shape is comprised between 2.7 and 3, advantageously between 2.8 and 2.9, and for example approximately 2.86.

According to one embodiment of the disclosure, a ratio of the third edge of each photovoltaic coating to a side of the equilateral triangular shape is comprised between 1.2 and 1.8, advantageously between 1.3 and 1.7, and even more advantageously between 1.4 and 1.6.

According to one embodiment of the disclosure, a ratio of the height of the three-dimensional photovoltaic module to a side of the equilateral triangular shape is comprised between 2.5 and 3.5, advantageously between 2.8 and 3.3, and for example between 3 and 3.1.

According to one embodiment of the disclosure, the three-dimensional support structure includes a plurality of support elements distributed about the central axis, each support element having an apex and two support faces which are substantially planar and which are connected to each other along a ridge area, the ridge area of each of the support elements being inclined relative to the central axis and extending to the apex of the respective support element while getting away from the central axis.

According to one embodiment of the disclosure, the first edge of each photovoltaic coating extends along and close to a respective ridge area.

According to one embodiment of the disclosure, the two photovoltaic coatings belonging to the same sub-assembly are disposed respectively on the support faces provided on the same support element.

According to one embodiment of the disclosure, for each pair of adjacent support elements of the three-dimensional support structure, the adjacent support faces of the two adjacent support elements are located opposite each other.

According to one embodiment of the disclosure, for each pair of adjacent support elements of the three-dimensional support structure, the adjacent support faces of the two adjacent support elements are connected to each other along a connecting area which is inclined relative to the central axis of the three-dimensional photovoltaic module and which extends downwardly and away from the central axis.

According to one embodiment of the disclosure, each ridge area forms a ridge line. Advantageously, each ridge line is straight.

According to another embodiment of the disclosure, each ridge area forms a ridge surface having a width comprised between 1 mm and 1 cm, and for example comprised between 1 mm and 5 mm. Advantageously, each ridge surface is substantially planar.

According to one embodiment of the disclosure, the apex of each support element is pointed.

According to another embodiment of the disclosure, the apex of each support element is truncated.

According to another embodiment of the disclosure, the two photovoltaic coatings belonging to the same sub-assembly protrude beyond the apex of the respective support element.

According to one embodiment of the disclosure, all the support faces belonging to the three-dimensional support structure have different orientations.

According to one embodiment of the disclosure, the apexes of the support elements are distributed, and for example regularly distributed, about the central axis.

According to one embodiment of the disclosure, the apexes of the support elements are equidistant from the central axis. In other words, the apexes of the support elements are disposed on a circle centered on the central axis.

According to one embodiment of the disclosure, the ridge lines intersect at a point of intersection located substantially on the central axis.

According to one embodiment of the disclosure, each of the ridge areas is inclined relative to the central axis by an angle of inclination comprised between 10 and 40°, advantageously between 20 and 30°, and for example approximately 26°.

According to one embodiment of the disclosure, each of the support faces has a generally triangular shape or a truncated triangular shape.

According to one embodiment of the disclosure, the number of support elements is comprised between 3 and 6.

According to one embodiment of the disclosure, the two support faces of each support element are symmetrical with respect to a respective plane of symmetry passing through the respective ridge area.

According to one embodiment of the disclosure, the planes of symmetry of the support elements intersect along a line of intersection which is substantially coincident with the central axis.

According to one embodiment of the disclosure, the three-dimensional photovoltaic module further includes a base which is located below the three-dimensional support structure and which defines, at least in part, an internal housing in which are housed at least in part the electrical connection devices, and for example the electrical connection wires connected to the photovoltaic coatings.

According to one embodiment of the disclosure, the base has a polygonal shape, and for example generally hexagonal.

According to one embodiment of the disclosure, the three-dimensional support structure is formed in one piece.

According to another embodiment of the disclosure, the support elements of the three-dimensional support structure are distinct from one another, and the three-dimensional support structure is formed by an assembly of the support elements.

According to one embodiment of the disclosure, the three-dimensional photovoltaic module includes a protective cover, also called an encapsulation cover, which covers the photovoltaic coatings, the protective cover being made of a material transparent to light radiation.

According to one embodiment of the disclosure, the protective cover is configured to at least in part fill an internal space located between the photovoltaic coatings.

According to one embodiment of the disclosure, the protective cover is formed by hardening a transparent resin.

According to one embodiment of the disclosure, the three-dimensional photovoltaic module includes an anti-reflective surface coating disposed on an upper face of the protective cover.

According to one embodiment of the disclosure, the upper face of the protective cover extends substantially perpendicular to the central axis of the three-dimensional photovoltaic module.

According to one embodiment of the disclosure, the upper face of the protective cover extends beyond the three-dimensional support structure, and for example beyond the apexes of the support elements.

According to one embodiment of the disclosure, the three-dimensional photovoltaic module has a cross-sectional shape that is polygonal, for example hexagonal.

According to one embodiment of the disclosure, the three-dimensional photovoltaic module has a height comprised between 3 and 6 cm, and for example approximately of 4 cm. Such a height of three-dimensional photovoltaic module is particularly chosen when the three-dimensional photovoltaic module is intended to be installed on inclined or horizontal roofs. The three-dimensional photovoltaic module could however have a height much greater than 6 cm for other applications, for example when the three-dimensional photovoltaic module is intended to be installed in a substantially vertical orientation.

According to one embodiment of the disclosure, the three-dimensional photovoltaic module comprises a positive main terminal to which the positive terminals of all the photovoltaic coatings are electrically connected, and a negative main terminal to which the negative terminals of all the photovoltaic coatings are electrically connected.

The present disclosure further includes a photovoltaic device including a plurality of three-dimensional photovoltaic modules according to the present disclosure, said three-dimensional photovoltaic modules being disposed adjacently. Advantageously, the photovoltaic device extends along a plane of extension.

According to one embodiment of the disclosure, for each pair of adjacent three-dimensional photovoltaic modules of the photovoltaic device, the bases of the two adjacent three-dimensional photovoltaic modules are juxtaposed, that is to say are in contact with each other. Advantageously, one side of a base of a three-dimensional photovoltaic module is configured to extend along and to be in contact with one side of a base of an adjacent three-dimensional photovoltaic module.

### BRIEF DESCRIPTION OF THE FIGURES

The present disclosure will be better understood with the aid of the following description with reference to the appended figures, in which identical reference signs correspond to structurally and/or functionally identical or similar elements.

FIG. 1 is an exploded schematic view of a three-dimensional photovoltaic module according to the present disclosure.

FIG. 2 is a top perspective view of a three-dimensional support structure belonging to the three-dimensional photovoltaic module of FIG. 1, showing the fastening of photovoltaic coatings to the three-dimensional support structure.

FIG. 3 is a top view of the three-dimensional support structure of FIG. 2 equipped with photovoltaic coatings.

FIG. 4 is a schematic side perspective view of the three-dimensional support structure of FIG. 2 equipped with photovoltaic coatings.

### DETAILED DESCRIPTION OF THE FIGURES

In the present document, the term “photovoltaic coating” means a photovoltaic element comprising at least one or several photovoltaic cell(s) supported or not by a base substrate layer which may for example be flexible or rigid.

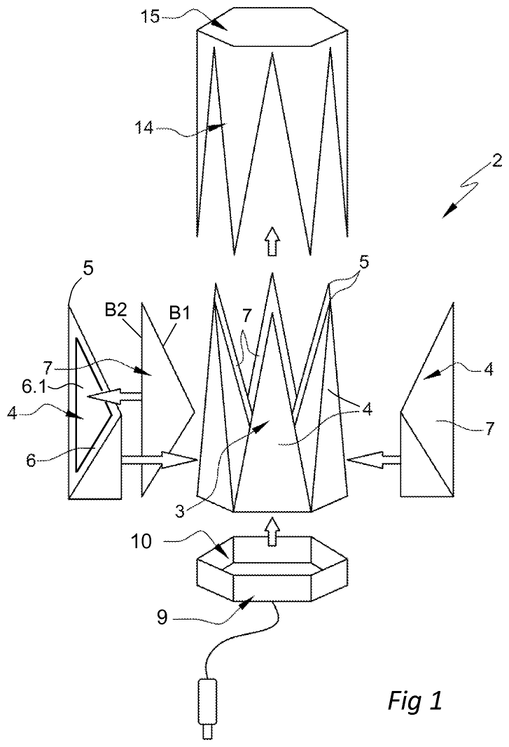

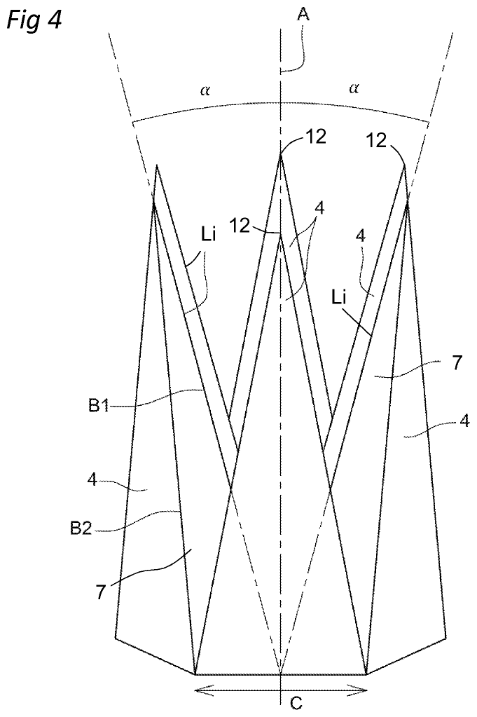

FIGS. 1 to 4 represent a three-dimensional photovoltaic module 2 according to one embodiment of the disclosure. Advantageously, the three-dimensional photovoltaic module 2 has a central axis A which is configured to extend vertically when the three-dimensional photovoltaic module 2 is disposed on a horizontal surface, and a cross-sectional shape that is polygonal, for example hexagonal.

The three-dimensional photovoltaic module 2 includes a three-dimensional support structure 3 including a plurality of support elements 4 distributed about the central axis A. Advantageously, the number of support elements 4 is comprised between 3 and 6. According to the embodiment shown in the figures, the number of support elements 4 is equal to 6. However, in one variant of the disclosure, the number of support elements 4 could be equal to 3, 4 or 5.

The three-dimensional support structure 3 may for example be formed in one piece, and be obtained for example by 3D printing. However, the three-dimensional support structure 3 could also be obtained by assembling a plurality of support elements 4 distinct from one another, that is to say formed independently from one another, for example by 3D printing.

Each support element 4 includes an apex 5 and two support faces 6 which are substantially planar. As also shown in FIG. 3, the apexes 5 of the support elements 4 are regularly distributed about the central axis A, and are equidistant from the central axis A. In other words, the apexes 5 of the support elements 4 are disposed on a circle centered on the central axis A. According to the embodiment shown in the figures, the apex 5 of each support element 4 is pointed. However, according to one variant of the disclosure, the apex 5 of each support element 4 could be truncated.

The two support faces 6 of each support element 4 are connected to each other along a ridge area. According to the embodiment shown in the figures, each ridge area is a ridge line Lc which is rectilinear. The ridge line Lc of each of the support elements 4 is inclined relative to the central axis A, and extends to the apex 5 of the respective support element 4 while getting away from the central axis A. Advantageously, the ridge lines Lc intersect at a point of intersection located on the central axis A, and are regularly distributed about the central axis A. Each of the ridge lines Lc is more particularly inclined relative to the central axis A by an angle of inclination comprised between 10 and 40°, advantageously between 20 and 30°, and for example approximately 26°.

However, according to one variant of the disclosure, each ridge area could be a ridge surface which is substantially planar and which has a width comprised between 1 mm and 1 cm, and for example comprised between 1 mm and 5 mm.

Advantageously, all the support faces 6 of the support elements 4 have different orientations, and each of the support faces 6 has a generally triangular shape. However, according to one variant of the disclosure, each of the support faces 6 could have a truncated triangular shape, that is to say a triangular shape of which at least one of the corners would be truncated, and for example the corner located on the side of the respective apex 5.

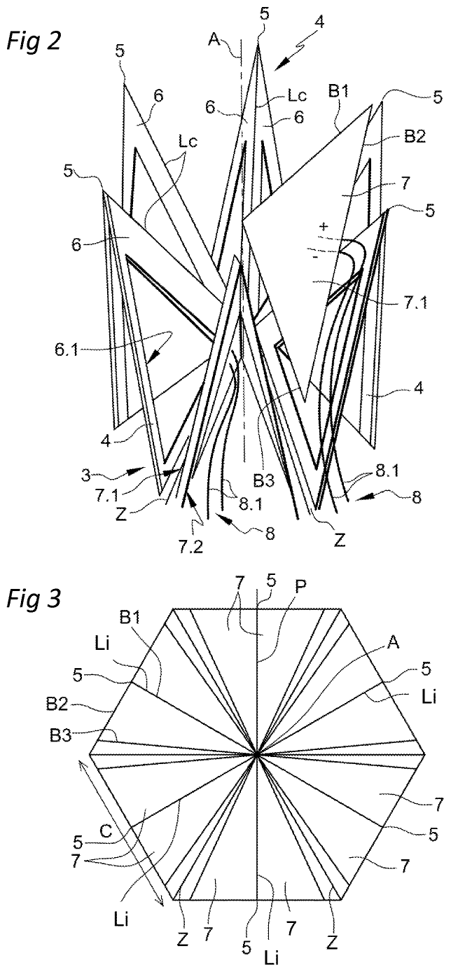

As shown more particularly in FIG. 2, for each pair of adjacent support elements 4 of the three-dimensional support structure 3, the adjacent support faces 6 of the two adjacent support elements 4 are located opposite each other. Advantageously, for each pair of adjacent support elements 4 of the three-dimensional support structure 3, the adjacent support faces 6 of the two adjacent support elements 4 are connected to each other along a connecting area Z which is inclined relative to the central axis A and which extends downwardly while getting away from the central axis A.

According to the embodiment shown in the figures, each support element 4 has a plane of symmetry P passing through the respective ridge line Lc, and the planes of symmetry P of the support elements 4 intersect along a line of intersection which coincides with the central axis A.

The three-dimensional photovoltaic module 2 further includes photovoltaic coatings 7 fastened to the three-dimensional support structure 3. According to the embodiment shown in the figures, the photovoltaic coatings 7 are distinct from one another and connected in series and/or in parallel. At least one photovoltaic coating 7, and for example each of the photovoltaic coatings 7, may be flexible or rigid. Each photovoltaic coating 7 is disposed on a respective support face 6, and extends parallel to the respective support face 6. Each photovoltaic coating 7 extends more particularly substantially along a respective plane of extension, and all the planes of extension of the photovoltaic coatings 7 have different orientations.

Each photovoltaic coating 7 advantageously comprises several photovoltaic cells connected in parallel and/or in series, and partially or completely covers the respective support face 6. The photovoltaic cells of each photovoltaic coating 7 may for example be supported by a base substrate layer.

Each photovoltaic coating 7 includes an active face 7.1 configured to capture photons of incident light rays, and a passive face 7.2 which is configured to be oriented towards the respective support face 6 and which is provided with a negative terminal and a positive terminal. The three-dimensional photovoltaic module 2 more particularly includes electrical connection devices 8 each configured to be electrically connected to the negative and positive terminals of a respective photovoltaic coating 7. For this purpose, each support face 6 is advantageously perforated and includes a through opening 6.1 (such as a window or a notch) configured to allow an electrical connection between the negative and positive terminals of the respective photovoltaic coating 7 and the respective electrical connection device 8. According to the embodiment shown in the figures, each electrical connection device 8 includes two electrical connection wires 8.1 which extend through the respective through opening 6.1 and which are respectively connected to the negative and positive terminals of the respective photovoltaic coating 7.

However, according to one variant of the disclosure, each electrical connection device 8 could for example include a printed circuit board fastened to the three-dimensional support structure 3 and provided with conductive tracks configured to be electrically connected to the negative and positive terminals of the respective photovoltaic coating 7, or could also include conductive tracks directly provided on the three-dimensional support structure 3 (the conductive tracks can for example be etched and/or printed on the three-dimensional support structure 3).

Advantageously, each photovoltaic coating 7 is generally triangular in shape, and has dimensions substantially identical to those of each support face 6. According to one embodiment of the disclosure, each photovoltaic coating 7 has a thickness of approximately 1 mm.

The photovoltaic coatings 7 comprise a plurality of sub-assemblies of photovoltaic coatings which are distributed about the central axis A and which each include two adjacent photovoltaic coatings 7. The two photovoltaic coatings 7 belonging to the same sub-assembly are disposed respectively on the support faces 6 provided on the same support element 4, and the adjacent photovoltaic coatings 7 belonging to two adjacent sub-assemblies are located opposite each other.

The planes of extension of the two photovoltaic coatings 7 belonging to the same sub-assembly intersect along a respective line of intersection Li which is inclined relative to the central axis A and which extends upwards and away from the central axis A. Each of the lines of intersection Li is inclined relative to the central axis A by an angle of inclination a comprised between 10 and 40°, advantageously between 20 and 30°, and for example approximately 26°. Advantageously, the lines of intersection Li are regularly distributed about the central axis A of the three-dimensional photovoltaic module 2, and intersect at a point of intersection located substantially on the central axis A of the three-dimensional photovoltaic module 2.

According to the embodiment shown in the figures, the two photovoltaic coatings 7 of each sub-assembly define an apex area 12, and the apex areas 12 defined by the photovoltaic coatings 7 are regularly distributed about the central axis A and are equidistant from the central axis A.

Each of the photovoltaic coatings 7 includes a first edge B1 extending along and close to the respective line of intersection Li, a second edge B2 located opposite the central axis A and extending to the respective apex area 12 and a third edge B3 connecting the respective first and second edges. Thus, the first edges B1 of two photovoltaic coatings 7 belonging to the same sub-assembly extend along and close to each other.

Advantageously, the second edge B2 of each photovoltaic coating 7 is inclined relative to the central axis A, such that the lower end of said second edge B2 is closer to the central axis A than the upper end of said second edge B2.

According to the embodiment shown in the figures, the two photovoltaic coatings 7 of each sub-assembly define, in top view, a triangular shape, and for example an equilateral triangular shape. In other words, an orthogonal projection of all the points of the two photovoltaic coatings 7 belonging to the same sub-assembly on a reference plane perpendicular to the central axis A defines a surface of triangular shape, and preferably of equilateral triangular shape.

According to one embodiment of the disclosure, the ratio of the developed surface of the photovoltaic coatings 7 to the ground surface occupied by the three-dimensional photovoltaic module 2 is greater than 3, and for example comprised between 4 and 6, and advantageously between 4.5 and 5.5.

According to one embodiment of the disclosure:
a ratio of the first edge B1 of each photovoltaic coating 7 to a side C of the equilateral triangular shape (defined by each support element 4 in top view) is comprised between 1.7 and 2.2, advantageously between 1.8 and 2, still advantageously between 1.90 and 1.95, and for example equal to approximately 1.94 or approximately 1.92,
a ratio of the second edge B2 of each photovoltaic coating 7 to a side C of the aforementioned equilateral triangular shape is comprised between 2.7 and 3, advantageously between 2.8 and 2.9, and for example approximately 2.86,
a ratio of the third edge B3 of each photovoltaic coating 7 to a side C of the aforementioned equilateral triangular shape is comprised between 1.2 and 1.8, advantageously between 1.3 and 1.7, and even more advantageously between 1.4 and 1.6, and for example equal to approximately 1.47 or approximately 1.58,
a ratio of the height of the three-dimensional photovoltaic module 2 to a side C of the aforementioned equilateral triangular shape is comprised between 2.5 and 3.5, advantageously between 2.8 and 3.3, and even more advantageously between 3 and 3.1, and for example equal to approximately 3.06.

Advantageously, each photovoltaic coating 7 is inclined, relative to a respective reference plane which is parallel to the central axis A and which passes through the third edge B3 of said photovoltaic coating 7, by an angle of inclination comprised between 5 and 10°, and for example approximately 7°.

The three-dimensional photovoltaic module 2 also includes a base 9 which is located below the three-dimensional support structure 3 and which has a polygonal shape, and for example generally hexagonal. The base 9 delimits, at least in part, an internal housing 10 in which the electrical connection wires 8.1 connected to the photovoltaic coatings 7 are housed at least in part.

The three-dimensional photovoltaic module 2 further comprises a positive main terminal to which the positive terminals of all the photovoltaic coatings 7 are electrically connected, and a negative main terminal to which the negative terminals of all the photovoltaic coatings 7 are electrically connected.

As shown in FIG. 1, the three-dimensional photovoltaic module 2 further includes a protective cover 14, also called an encapsulation cover, which covers and protects the photovoltaic coatings 7. The protective cover 14 is made of a material transparent to light radiation, and is for example formed by hardening a transparent resin. The protective cover 14 is more particularly configured to fill an internal space located between the photovoltaic coatings 7.

According to the embodiment shown in the figures, the protective cover 14 includes an upper face which extends beyond the apexes 5 of the support elements 4, and which extends perpendicular to the central axis A. Advantageously, the protective cover 14 is configured such that the three-dimensional photovoltaic module 2 has a general prism shape, each of the bases of which has a generally hexagonal shape.

The three-dimensional photovoltaic module 2 also includes an anti-reflective surface coating 15 disposed on the upper face of the protective cover 14. However, if the protective cover 14 is made of a material having anti-reflective properties, the three-dimensional photovoltaic module 2 could be devoid of the anti-reflective surface coating 15.

According to one embodiment of the disclosure not shown in the figures, the apex 5 of each support element 4 could be truncated, and the two photovoltaic coatings 7 belonging to the same sub-assembly could protrude beyond the apex 5 of the respective support element 4.

Several three-dimensional photovoltaic modules 2 according to the present disclosure could be assembled so as to form a photovoltaic device extending along a plane of extension, and therefore having an external shape similar to that of a conventional photovoltaic panel. For this purpose, the three-dimensional photovoltaic modules 2 are disposed adjacently, and are connected in series and/or in parallel by connecting their main positive and negative terminals. Advantageously, for each pair of adjacent three-dimensional photovoltaic modules 2 of the photovoltaic device, the bases 9 of the two adjacent three-dimensional photovoltaic modules 2 are juxtaposed, that is to say are in contact with each other, at their adjacent sides. Such a photovoltaic device advantageously includes a support or support frame delimiting a compartment in which the different three-dimensional photovoltaic modules 2 are disposed.

The fact that the base 9 of each three-dimensional photovoltaic module 2 has a hexagonal shape advantageously makes it possible to obtain an optimized network arrangement of the different three-dimensional photovoltaic modules 2 of said photovoltaic device.

A photovoltaic device according to the present disclosure can be installed in a greater number of locations than a photovoltaic device formed of three-dimensional photovoltaic modules of the prior art, and with fewer orientation and inclination constraints. A photovoltaic device according to the present disclosure can in particular be installed on inclined roofs facing East, South or West, on horizontal roofs or on the ground without additional support, on façades facing East, South or West (and therefore in a substantially vertical orientation), or even as a replacement for all existing photovoltaic devices coated with photovoltaic material having identical technical features with at least three times more annual electricity production for the same surface area.

A photovoltaic device according to the present disclosure can also be installed on all existing and future vehicles, due to the fact that such a photovoltaic device has an annual energy production at least three times greater than that of photovoltaic devices of the prior art coated with photovoltaic material having identical technical features and is free from most orientation constraints.

Of course, the present disclosure is in no way limited to the described and illustrated embodiment, which has been given only as an example. Modifications remain possible, in particular from the point of view of the constitution of the various elements or by substitution of technical equivalents, without departing from the scope of protection of the disclosure.

1. A three-dimensional photovoltaic module provided with a central axis and including:
a three-dimensional support structure comprising a plurality of support faces distributed about the central axis,
photovoltaic coatings fastened to the three-dimensional support structure, each photovoltaic coating being disposed on a respective support face and covering at least partially the respective support face, each photovoltaic coating extending substantially along a respective plane of extension and comprising at least one photovoltaic cell,
the photovoltaic coatings comprising a plurality of sub-assemblies of photovoltaic coatings which are distributed about the central axis and which each include two adjacent photovoltaic coatings, the planes of extension of the two photovoltaic coatings belonging to the same sub-assembly converging upwards and intersecting along a respective line of intersection which is inclined relative to the central axis and which extends upwards and away from the central axis

2. The three-dimensional photovoltaic module according to claim 1, wherein each photovoltaic coating includes an active face configured to capture photons of incident light rays, and a passive face configured to be oriented towards the respective support face and provided with a negative terminal and a positive terminal.

3. Three-dimensional photovoltaic module according to claim 2, which includes electrical connection devices each configured to be electrically connected to the negative and positive terminals of a respective photovoltaic coating, each support face being perforated and including at least one through opening configured to allow an electrical connection between the negative and positive terminals of the respective photovoltaic coating and the respective electrical connection device.

4. The three-dimensional photovoltaic module according to claim 3, wherein each electrical connection device includes two electrical connection wires which extend through the respective through opening and which are connected respectively to the negative and positive terminals of the respective photovoltaic coating.

5. The three-dimensional photovoltaic module according to claim 3, which further includes a base which is located below the three-dimensional support structure and which defines, at least in part, an internal housing in which the electrical connection devices are at least partially housed.

6. The three-dimensional photovoltaic module according to claim 5, wherein the base has a polygonal shape.

7. The three-dimensional photovoltaic module according to claim 1, wherein the lines of intersection intersect at a point of intersection located substantially on the central axis of the three-dimensional photovoltaic module.

8. The three-dimensional photovoltaic module according to claim 1, wherein all the planes of extension of the photovoltaic coatings have different orientations.

9. The three-dimensional photovoltaic module according to claim 1, wherein the two photovoltaic coatings of each sub-assembly define an apex area said apex areas being distributed about the central axis.

10. The three-dimensional photovoltaic module according to claim 1, wherein each of the photovoltaic coatings has a generally triangular shape.

11. The three-dimensional photovoltaic module according to claim 10, wherein each photovoltaic coating includes a first edge extending along and close to the respective line of intersection a second edge located opposite the central axis and a third edge connecting the respective first and second edges.

12. The three-dimensional photovoltaic module according to claim 1, wherein each of the lines of intersection is inclined relative to the central axis by an angle of inclination comprised between 10 and 40°.

13. The three-dimensional photovoltaic module according to claim 1, wherein the number of support faces is comprised between 6 and 12.

14. The three-dimensional photovoltaic module according to claim 1, wherein the two photovoltaic coatings of each sub-assembly are substantially symmetrical with respect to a respective plane of symmetry passing through the respective line of intersection

15. The three-dimensional photovoltaic module according to claim 1, wherein the adjacent photovoltaic coatings belonging to two adjacent sub-assemblies are located opposite each other.

16. The three-dimensional photovoltaic module according to claim 1, wherein the three-dimensional support structure includes a plurality of support elements distributed about the central axis, each support element including an apex and two support faces which are substantially planar and which are connected to each other along a ridge area, the ridge area of each of the support elements being inclined relative to the central axis and extending to the apex of the respective support element while getting away from the central axis.

17. The three-dimensional photovoltaic module according to claim 1, which includes a protective cover which covers the photovoltaic coatings, the protective cover being made of a material transparent to light radiation.

18. The three-dimensional photovoltaic module according to claim 17, which includes an anti-reflective surface coating disposed on an upper face of the protective cover.

19. A photovoltaic device comprising a plurality of three-dimensional photovoltaic modules according to claim 1, said three-dimensional photovoltaic modules being disposed adjacently.
